(19) United States
(12) Patent Application Publication
(10) Pub. No.: US 2005/0194961 A1
(43) Pub. Date: Sep. 8, 2005

(54) On board built in test

(76) Inventors: Steven M. Summers, Hudson, NH (US); Thomas C. Horgan, Rowley, MA (US)

Correspondence Address: BAE SYSTEMS INFORMATION AND;ELECTRONIC SYSTEMS INTEGRATION INC., 65 SPIT BROOK ROAD, P.O. BOX 868 NHQ1-719, NASHUA, NH, 03061-0868, US

(21) Appl. No.: 10/793,366

(22) Filed: Mar. 4, 2004

(51) Int. Cl. H01Q 13/10; G01R 27/00

(52) U.S. Cl. 324/95

(57) ABSTRACT

A method and apparatus for substantially reducing the problems associated with prior methods and apparatus for measuring the RF characteristics of electronic circuitry. The method and apparatus allow “in-package” testing of microwave modules, or subassemblies, without the need for additional test fixtures. Preferably, the testing is based on a discontinuous transmission line and at least one waveguide. The discontinuous transmission line electrically isolates two or more modules so that they may be tested individually. The discontinuous transmission line may then be connected using, for example, a ribbon bond. Once the transmission line is connected, the two modules may be capable of communicating with one another. One advantage of the method and apparatus is that the RF characteristics of one or more modules may be determined in their actual operating environment. Another advantage is that there is substantially little detrimental affect on the performance of the modules and the overall circuit due to the discontinuous transmission line or waveguides.

### FIELD OF THE INVENTION

The present invention relates to a method and apparatus for testing microwave circuits. More specifically, the present invention allows in-package testing of microwave subassemblies without the need for additional test fixtures or substrates.

### BACKGROUND OF THE INVENTION

Producing electrical devices is often a time consuming and expensive process. Many factors affect the total cost of production, including manpower, materials, design, and testing.

Though the effect of factors such as manpower and materials can be reduced slightly, these costs are often necessary for the design of an electrical device. The design, testing, and re-designing of an electrical device often causes the greatest uncertainty in production costs. This is partially due to the fact that improper designing in initial stages can result in a greater need for testing and redesign.

Because design and testing costs may vary widely, these stages of production are ideal targets for cost reduction and increased efficiency. Many design and testing products are currently available to meet these goals. Some are hardware based, while others arc software based. Rudimentary hardware based testing products may be as simple as a voltmeter or oscilloscope. Similarly, the complexity of software based testing products may vary greatly.

Software based testing products may be used to design, test, and redesign devices before assembly.

Despite the wide array of products that are available for testing a device pre-production, it is sometimes necessary to test a device, or parts of a device, after it has been manufactured. This is typically true for devices such as microstripline circuits. When manufacturing these types of devices, it is often necessary to test each chip or module prior to assembly of the entire device. This allows the chip or module to be tested for proper design and function.

Many methods and apparatus are available for testing microstripline circuits. One type of apparatus uses coplanar waveguide to microstripline transitions so that a device, which is typically manufactured on a ceramic substrate, can be probed for testing using ground-signal-ground (GSG) probes. The coplanar waveguide allows points for the probe to contact for testing. After the chip is tested on a wafer and placed in a module, the signal portion of the coplanar waveguide is connected to the rest of the microstripline circuitry with a ribbon bond.

Another common method of testing microstripline circuits is to test a chip or series of chips by making a test fixture to house the chips. The chips are then biased so that they can be characterized. However, this approach results in errors due to the fixture, as well as RF connectors on the test fixture. Additionally, creating test fixtures is costly and can be time consuming.

Another testing apparatus involves specific microstripline circuits, called Monolithic Microwave Integrated Circuits (MMIC). This apparatus involves placing an MMIC on a substrate. Probepoints, which are adapter substrates, are used to test the MMIC. Probepoints are ceramic adapter substrates that provide coplanar waveguide to microstripline transitions so that a MMIC can be tested using GSG probes. However, this approach has several drawbacks. For instance, this apparatus is not practical since the test setup requires significant touch labor. Additionally, the test setup doesn't represent the environment that the circuitry will be used in because it does not have the same housing or surrounding devices. Lastly, it is difficult to bias a device using this apparatus, making this apparatus undesirable for accurate testing.

A continuing need exists for a method and apparatus that are capable of eliminating the drawbacks of prior testing apparatus and methods while allowing accurate testing and measurement of electrical devices.

### SUMMARY OF THE INVENTION

The present invention provides a method and apparatus for substantially reducing the problems associated with prior methods and apparatus for measuring the RF characteristics of electronic circuitry. The present invention provides a method and apparatus that allows “in-package” testing of microwave modules, or subassemblies, without the need for additional test fixtures. In other words, one or more modules may be tested within its actual housing, and with surrounding circuitry. One advantage of the present invention is that the RF characteristics of one or more modules may be determined in their actual operating environment. Another advantage is that the present invention has substantially little detrimental affect on the performance of the modules and the overall circuit.

In one embodiment, the present invention comprises an apparatus for testing one or more portions of an electrical device. The apparatus includes a discontinuous transmission line and at least one waveguide selectively positioned near each end of the discontinuity. It is desired that the one or more portions are tested without being removed from the electrical device. In some embodiments, the waveguide comprises a coplanar waveguide. Preferably, the discontinuous transmission line is selectively positioned between the one or more portions of the electrical device. In some embodiments, the discontinuous transmission line is operatively connected based on a ribbon bond. Once the ribbon bond operatively connects the discontinuous transmission line, the one or more portions of the electrical device are capable of communicating. In some embodiments, the electrical device may be manufactured onto a substrate. In these embodiments, the discontinuous transmission line and the at least one waveguide are preferably manufactured onto the substrate at substantially the same time as the electrical device. This provides the advantage of reducing the cost of adding the coplanar waveguides. Preferably, the total additional cost of manufacturing the discontinuous transmission line and the at least one waveguide onto the substrate is less than about 1%. More preferably, the total additional cost of manufacturing the discontinuous transmission line and the at least one waveguide onto the substrate is less than about 0.5%.

In another embodiment, the present invention comprises an apparatus for testing an electrical device. The apparatus includes a discontinuous transmission line and at least two coplanar waveguides selectively positioned near each end of the discontinuity. In one embodiment, the discontinuous transmission line is selectively positioned between two or more portions of the electrical device. Preferably, the electrical device comprises a microstripline circuit.

In yet another embodiment, the present invention comprises a method for testing an electrical device having two or more portions. The method includes electrically isolating the two or more portions based on a discontinuous transmission line. The at least two waveguides are then selectively positioned near each end of the discontinuous transmission line. In one embodiment, the two or more portions may be tested without being removed from the electrical device. Each of the two or more portions may be tested by probing the discontinuous transmission line and the at least two waveguides. In some embodiments, the probing may be accomplished by selectively positioning a GSG probe.

### BRIEF DESCRIPTION OF THE DRAWINGS

FIG. 1A is a diagram showing an exemplary embodiment of the present invention;

FIG. 1B is a diagram showing an exemplary embodiment of a straight transmission line;

FIG. 2 is a diagram showing one example of the placement of lobes according to the present invention;

FIG. 3 is a diagram showing another example of the placement of lobes according to the present invention;

FIG. 4 is a diagram showing an exemplary embodiment of the present invention;

FIG. 5 is a graph showing the electrical characteristics of the FIG. 2 embodiment;

FIG. 6 is a graph showing the electrical characteristics of a straight transmission line according to the present invention;

FIG. 7 is a graph showing the electrical characteristics of the FIG. 3 embodiment;

FIG. 8A is a graph showing a comparison of the magnitude of reflectance between a straight transmission line and a transmission line with an OrBIT; and

FIG. 8B is a graph showing a comparison of the magnitude of loss between a straight transmission line and a transmission line with an OrBIT.

### DETAILED DESCRIPTION OF THE PREFERRED EMBODIMENTS

An integral part of the manufacturing of electrical devices is the design and testing of components that are included in the electrical device. Complex electrical devices often include several modules. Each module performs one or more functions, and may be manufactured separately. Each module is typically manufactured with appropriate connects so that it may be operatively connected to other modules to form a functional electrical device.

Manufacturers often use a module approach to designing and constructing complex electrical devices because this approach facilitates design and testing. Each module may be tested individually to verify that it is operating correctly. After verifying the correct operation of the modules, they may be connected together. However, testing does not always end at the module level. Often when one or more modules are connected together, problems arise. This may be caused by incompatible parts, electrical interference, improper grounding, or the like. Alternately, it may be caused by improper connections between modules, or for any other reason known to those skilled in the art. Thus, to verify the correct operation of a device, it may be desirable to test one or more modules individually and collectively.

Prior methods and apparatus for testing electrical circuits involved manufacturing separate test fixtures. The construction of these test fixtures is typically labor intensive and costly. In addition, because the test fixtures are often used to measure the Radio Frequency (RF) characteristics of circuits, the test fixtures may cause errors in the measurements. Thus, the RF characteristics of the circuits cannot be accurately measured. Additionally, test fixtures require removing a circuit or module from a circuit and placing it into the test fixture. Many devices are too delicate to be removed and reused. Typically, if a device is removed, it is destroyed in the process. Therefore, the functionality of a given device cannot be ascertained using a test fixture.

The present invention provides a method and apparatus for substantially reducing the problems associated with prior methods and apparatus for measuring the RF characteristics of electronic circuitry. The present invention provides a method and apparatus that allows “in-package” testing of microwave modules, or subassemblies, without the need for additional test fixtures. In other words, one or more modules may be tested within its actual housing, and with surrounding circuitry. One advantage of the present invention is that the RF characteristics of one or more modules may be determined in their actual operating environment. Another advantage is that the present invention has substantially little detrimental affect on the performance of the modules and the overall circuit.

Microstripline (“MS”) circuits are often used in the telecommunications, aerospace, and microelectronics industry. This type of circuit is essentially a planar waveguide fabricated in a similar manner to an integrated circuit, or printed onto a substrate. Electromagnetic energy propagates along the waveguide and into the surrounding dielectric media at microwave frequencies and cannot be analyzed using low-frequency current conduction principles. These circuits are well known to those skilled in the art.

In order to analyze the operation of microwave circuits, special probes are often used. The two most common styles of probes are the Ground-Signal (“GS”) and Ground-Signal-Ground (GSG) probes. As is well known to those skilled in the art, a GS probe effectively creates an electric dipole, while a GSG probe has two opposed dipoles that tend to cancel the transverse electric field of each other. The present invention is capable of being used with either type of probe. However, in one embodiment, a GSG probe is preferred. GSG probes provide the advantage of increased accuracy and lower costs than previous methods of measuring RF characteristics.

As described previously, prior methods often require a module to be placed into a test fixture that provides power, ground, and signal paths. This is expensive and labor intensive. The present invention provides an apparatus for accommodating either GS or GSG probes. In one embodiment, the signal portion of the GSG probe contacts the microstrip area. Additionally, the present invention comprises at least two paths to ground positioned around the microstrip area such that testing of a module can be done in its operating environment.

In one embodiment, each module is manufactured and placed into a housing. To allow each module to communicate with other modules, a transmission line may be placed in between the modules. Each transmission line preferably comprises a microstripline circuit manufactured on a substrate. Each transmission line is placed between two modules such that it operatively connects the two modules. The transmission line and the modules may be connected together in any desired manner. It is desirable to use a connection apparatus that is reliable and minimizes cost, while allowing the module and transmission line to be connected with minimal touch labor. In some embodiments, the modules may be connected to the transmission line through the use of ribbon bonds.

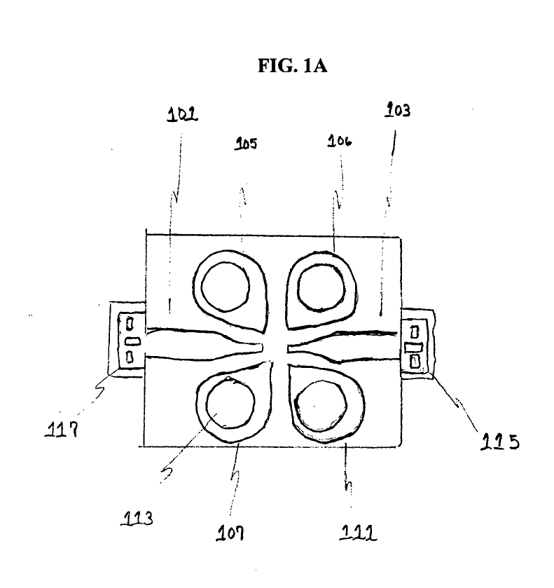

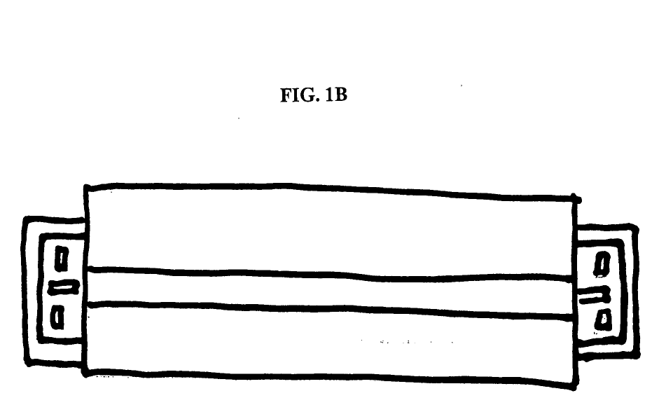

In one embodiment, shown in FIG. 1a, the present invention comprises four lobes 105-111 positioned around a discontinuous transmission line. The four lobes 105-111 are preferably manufactured onto the same substrate as the transmission line. Typically, manufacturer's attempt to minimize the costs of designing, testing, and manufacturing equipment so that they can maximize their profits. Manufacturing the four lobes 105-111 onto the same substrate as the transmission line substantially minimizes the cost of adding the lobes 105-111.

One advantage of manufacturing the lobes 105-111 onto the same substrate as the transmission line is that the lobes may be manufactured using the same method that is used to manufacture the transmission line. Thus, the additional cost of manufacturing the lobes may be minimized further. In one embodiment, the transmission line and the lobes 105-111 are etched onto a substrate at substantially the same time. Thus, the addition of the lobes to the substrate does not require additional manufacturing processes, thereby minimizing their cost.

Preferably, the total additional cost of manufacturing lobes 105-111 onto a substrate is less than about 2% of the total cost of manufacturing the transmission line. More preferably the total additional cost is less than about 1%, and most preferably the total additional cost is less than about 0.5%.

As described above, the transmission line shown in the FIG. 1a embodiment comprises a discontinuous transmission line. The discontinuous transmission line includes two separate transmission lines 101 and 103. When the transmission lines are discontinuous, signals cannot travel between lines 101 and 103. In order to operatively connect lines 101 and 103, any bond known to those skilled in the art may be used.

In a preferred embodiment, a ribbon bond is used to connect transmission lines 101 and 103 so that they act as a substantially straight transmission line. Ribbon bonds are formed by bonding ribbon wire to each transmission line 101 and 103. In embodiments where a high frequency electrical signal is being transmitted, ribbon bonds are especially useful. In such embodiments, high frequency signals travel along the thin layer of the wire near the surface, known as the skin effect to those skilled in the art. Ribbon wire has characteristics that reduce electrical interference with transmitted signals, such as low effective inductance and small signal cross talk. Additionally, the geometry of the contact area of ribbon wire more closely matches that of devices surfaces.

The ribbon wire used to connect the transmission lines 101 and 103 may comprise any material or combination of materials known to those skilled in the art. In some embodiments, the ribbon wire may be manufactured from gold, copper, or the like. In other embodiments, the ribbon wire may comprise a first material that is plated with a second material. For example, in some embodiments a ribbon wire may be copper with gold plating. Plating a ribbon wire with a second material often reduces the expense of the wire while providing a high conductivity material on the surface of the wire. One advantage of having a high conductivity material on the surface of the wire is that the high conductivity material allows the ribbon wire to accommodate the skin effect, as described above.

In one embodiment, each of the lobes 105-111 comprise coplanar waveguides. Each lobe 105-107 is selectively positioned around transmission line 101 such that a GSG probe may be used to detect a signal traveling over transmission line 101. The two lobes are preferably positioned sufficiently close to the transmission line 101 such that a probe is capable of contacting the lobes 105-107 and the transmission line 101 at the same time. Lobes 109 and 111 are similarly positioned around transmission line 103.

As shown in FIG. 1A, each lobe 105-111 comprises a coplanar waveguide. Each coplanar waveguide includes an via 113, which makes the ground connection for the coplanar waveguide. In the embodiment shown in FIG. 1A, the coplanar waveguide may be used to test a particular section of a circuit. One advantage of this embodiment is that the circuitry that is being probed does not have to be removed and placed into a separate test fixture. This allows the electrical measurements to be accurate and reflect the circuitry surroundings. Another advantage of the FIG. 1A embodiment is that the cost of adding lobes 105-111 is minimized because they are etched onto the substrate at the same time as the transmission lines. Once the circuitry has been tested, transmission lines 101 and 103 may be connected by a bond, such as a ribbon bond or the like, in order to form a straight transmission line. One example of a straight transmission line is shown in FIG. 1B.

In one embodiment, the dimensions of each lobe 105-111 may be varied according to the substrate material. Typically, it is desirable to have the vias 113 of a coplanar waveguide at least five times wider than the signal conducting portion. This provides the advantage of allowing better impedance control and lower loss.

Additionally, the position of each lobe 105-111 relative to each transmission line 101 and 103 may also be varied according to the type of substrate being used. Any substrate known to those skilled in the art may be used. In one embodiment, the substrate comprises glass filled or ceramic filled polytetrafluoroethylene (PTFE) material such as Rogers 6002 or 3003.

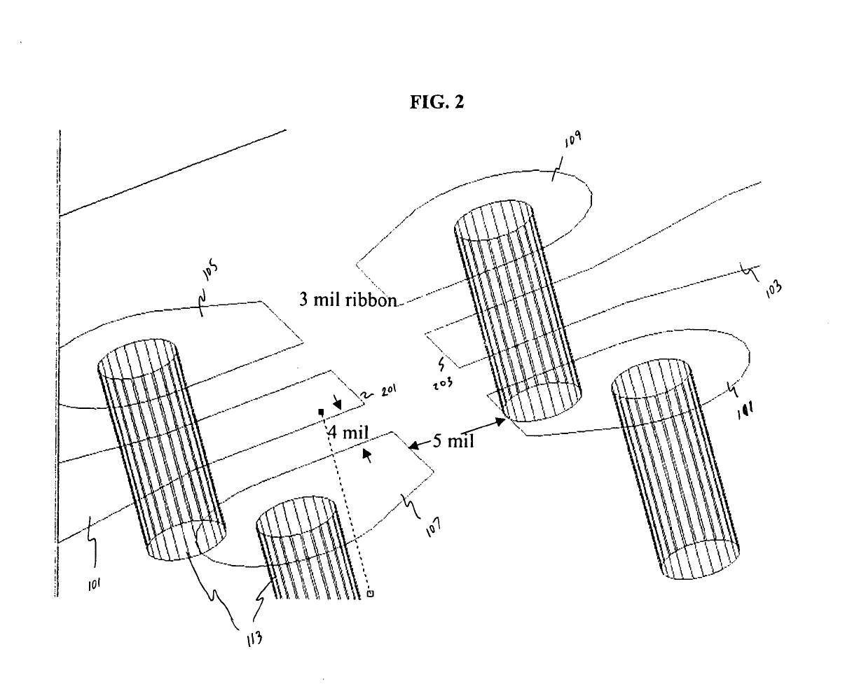

One example of the positioning of the lobes 105-111 is shown in FIG. 2. In this embodiment, the lobes 105-111, vias 113, and transmission lines 101 and 103 are shown. In this embodiment, the width of the transmission line is about 5 mils or less. In the FIG. 2 embodiment, the distance between the ends 201 and 203 of transmission lines 101 and 103 is about 5 mil or less. The distance between lobes 105 and 109 and between lobes 107 and 111 is also about 5 mil or less. The distance between each lobe 105-111 and their respective transmission lines 101-103 is about 4 mil or less, as shown in FIG. 2. In this embodiment, the width of the ribbon bond that is used to connect transmission lines 101 and 103 is preferably about 3 mil or less. The electrical characteristics of this embodiment in comparison to a straight transmission line will be discussed in more detail below.

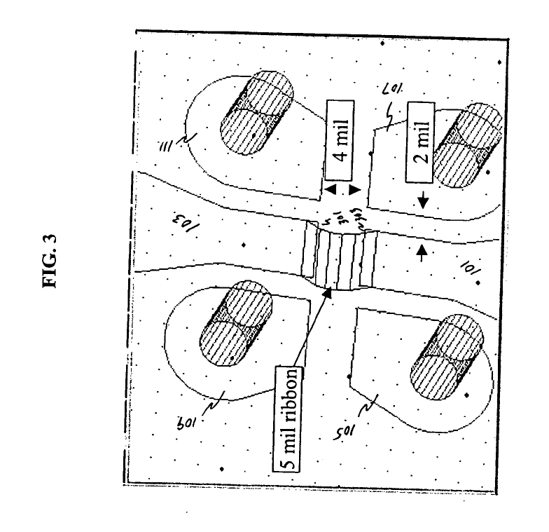

In another embodiment, shown in FIG. 3, the positioning of the lobes and the transmission lines may be varied. Preferably, the width of the transmission line and the coplanar waveguides are based on the desired impedance and the operating frequency, as is well known in the art. The distance between the ends of the transmission lines is preferably separated by a distance that is sufficient to isolate each of the transmission lines. In this embodiment, the distance between the ends 301-303 of each transmission line is preferably between about 3 and about 7 mils, and more preferably between about 4 and 5 mils. The distance between lobes 105 and 109 and between lobes 107 and 111 is about 5 mil. The distance between each lobe 105-111 and their respective transmission lines 101-103 is about 2 mil, as shown in FIG. 3. In this embodiment, the width of the ribbon bond that is used to connect transmission lines 101 and 103 is preferably about 5 mil or less. The electrical characteristics of this embodiment in comparison to a straight transmission line will be discussed in more detail below.

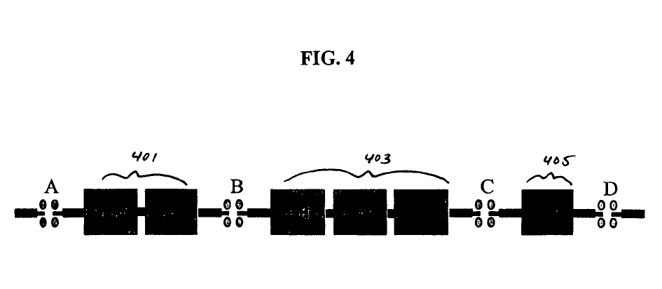

In one embodiment, as shown in FIG. 4, each module comprises a Microwave Monolithic Integrated Circuit (“MMIC”). In order to analyze the operation of two MMIC's, each MMIC is operatively connected to a transmission line. This may be accomplished in any desired manner. In one embodiment, each transmission line substrate includes ceramic connectors 115 and 117, shown in FIG. 1, which may be used to connect a module to an MMIC. Prefabricated ceramic connectors allow modules to be quickly attached and detached from a transmission line substrate, which increases the efficiency of the testing process and reduces the need for extensive touch labor.

In the FIG. 4 embodiment, modules may be connected together based on the transmission line shown in FIG. 1A. In this embodiment, a plurality of MMIC's are connected together for testing. Since the MMIC's are connected together as they would be in a functional circuit, they are biased in the configuration for which they are intended. Referring to FIG. 4, the testing of one or more MMIC's is described. Lobes 105-111 are shown in FIG. 4, and are collectively referred to as an OrBIT. By probing the right side of OrBIT A and the left side of OrBIT B, the first block of MMIC's may be tested. Likewise, probing the right side of OrBIT B and the left side of OrBIT C can test the second set of MMIC's. In this configuration, the individual blocks between each set of OrBIT's are operatively connected to each other. However, each set of blocks 401-405 are not operatively connected to each other until a ribbon bond is used to operatively connect the transmission lines.

After each block of MMIC's 401-403 are tested separately, a ribbon bond may be placed across the transmission line surrounded by OrBIT B. This operatively connects the MMIC's from block 401 and 403. Now, the first five MMIC's from blocks 401 and 403 may be tested in a chain by probing the right side of OrBIT A and the left side of OrBIT C. This embodiment may be particularly useful for initial build testing as well as troubleshooting. In this embodiment, ribbon bonds between transmission lines may be removed and reinstalled any desired number of times, without damaging the transmission lines.

When ribbon bonds are used to connect transmission lines 101 and 103, shown in FIG. 1A, they act as a straight transmission line like that shown in FIG. 1B. Preferably the impedance of the straight transmission line is between 48 and 52 Ohms. More preferably, the impedance of the straight transmission line is between about 49 and 51 Ohms, and most preferably the impedance is between about 49.5 and 50.5 Ohms.

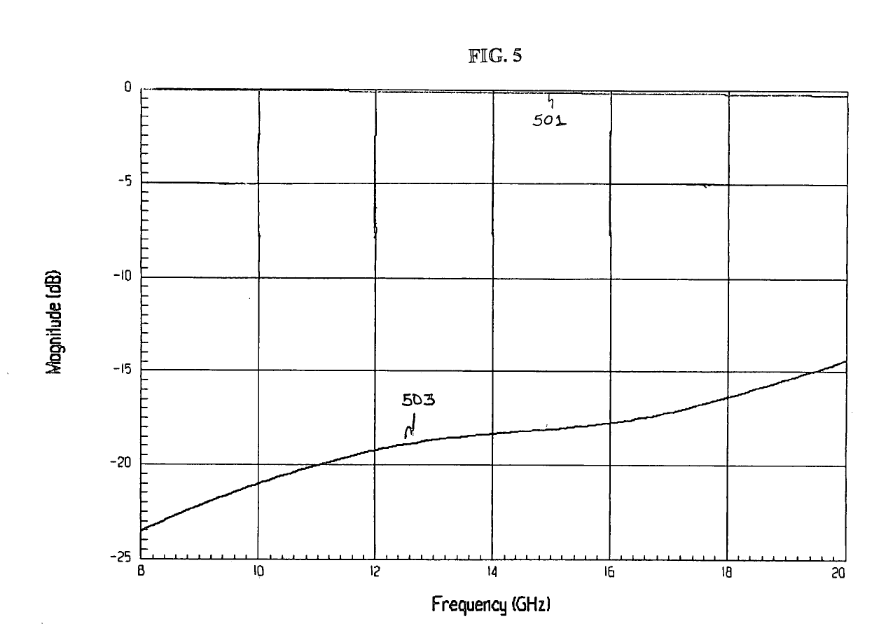

The present invention allows the electrical characteristics of a chip or module to be measured with substantially no degradation in performance. FIG. 5 is a graph showing the simulated electrical characteristics of the FIG. 2 embodiment. In this embodiment, the simulation is performed using, for example, HFSS by Ansoft. Magnitude measured in decibels (dB) is shown on the y-axis and Frequency measured in Gigahertz (GHz) is shown on the x-axis.

In FIG. 5, graph 501 shows that there is a significantly small amount of loss caused by the OrBIT's and the bonded transmission line. This is true for a wide frequency range. The second graph 503 shows that the magnitude of the transmission line reflection that results from the ribbon bond and the OrBIT is significantly small. As is well known to those skilled in the art, the magnitude of the reflectance is significantly small below −15 dB. As shown in FIG. 5, the magnitude of graph 503 is below −15 dB over a wide frequency range.

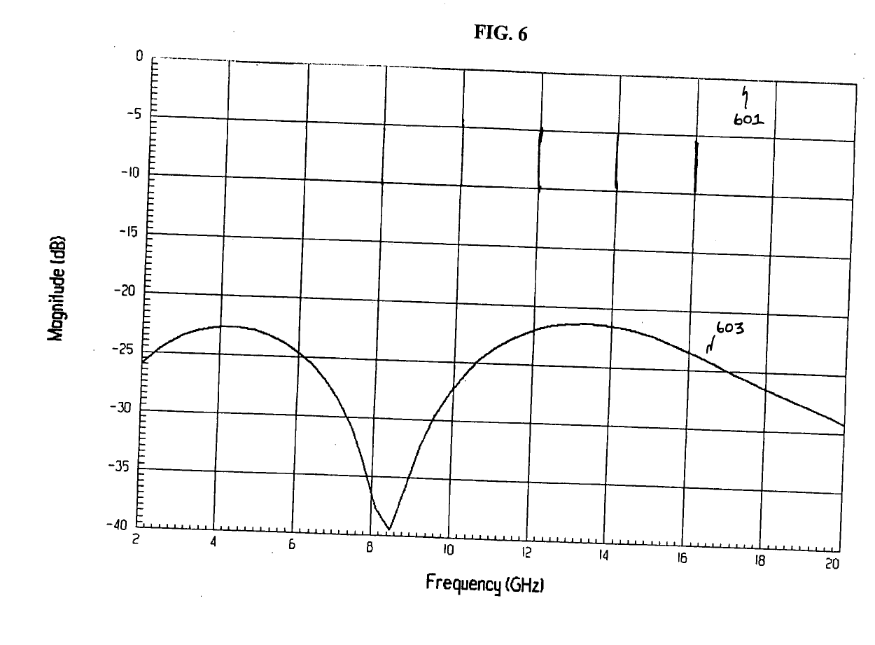

In addition to having a substantially small magnitude of reflection compared to other transmission lines used by those skilled in the art, the FIG. 5 graph may be compared to a simulation of a straight microstrip transmission line, as shown in FIG. 6. This comparison shows that a transmission line with an OrBIT functions in a substantially similar manner to a straight transmission line. The measurements on the FIG. 6 axes are the same as described with respect to FIG. 5.

Graph 601 shows that a straight transmission line has a substantially small amount of loss. When compared to graph 501 in FIG. 5, the loss of a straight transmission line and the loss of a ribbon bonded transmission line are substantially similar. FIG. 6 also shows graph 603, which represents the transmission line reflectance of a straight transmission line. As was described above, a reflectance magnitude below −15 dB is significantly small. Comparing graph 603 and graph 503 shows that the reflectance magnitude of a ribbon bonded transmission line and a straight transmission line are both significantly small. Thus, the embodiment shown in FIG. 2, the performance degradation due to the OrBIT is substantially small.

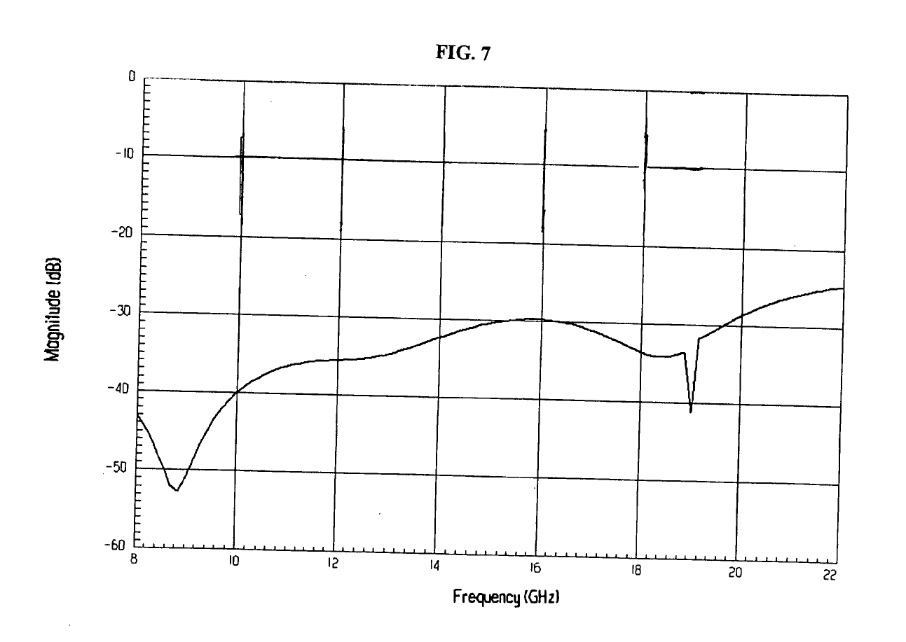

FIG. 7 is a graph showing the electrical characteristics of the FIG. 3 embodiment. The graph shows simulated electrical characteristics that are measured using a GSG probe. In this embodiment, the simulation is performed using, for example, HFSS by Ansoft. Magnitude measured in decibels (dB) is shown on the y-axis and Frequency measured in Gigahertz (GHz) is shown on the x-axis.

In FIG. 7, graph 701 shows that there is a significantly small amount of loss caused by the OrBIT's and the bonded transmission line. This is true for a wide frequency range. The second graph 703 shows that the transmission line reflection that results from the ribbon bond and the OrBIT is significantly small. As was described above, the magnitude of the reflectance is significantly small below −15 dB. As shown in FIG. 5, line 503 is below −20 dB over a wide frequency range. Thus, the magnitude of the reflectance for a transmission line with an OrBIT is lower than a straight transmission line.

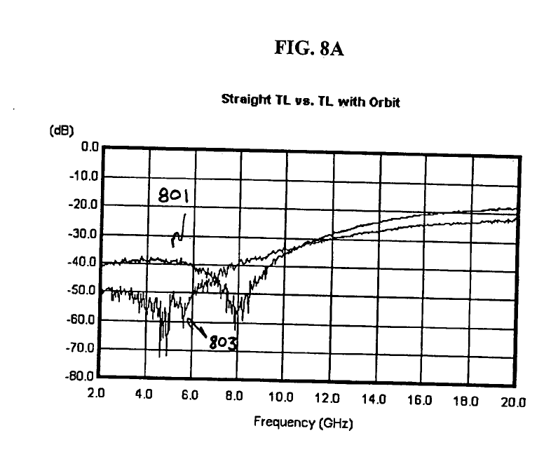

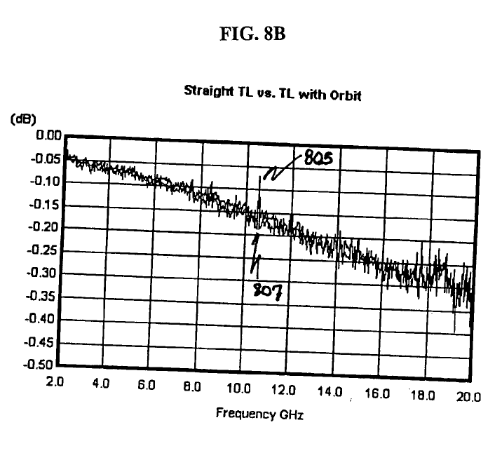

FIG. 8A is a graph showing a comparison of the magnitude of reflectance between a straight transmission line and a transmission line with an OrBIT. Magnitude measured in dB is shown on the y-axis, and frequency measured in GHz is shown on the x-axis. The FIG. 8A graphs are generated by testing a straight microstripline transmission line and a microstripline transmission line manufactured with an OrBIT.

The magnitude of reflectance of a straight transmission line is shown by graph 801 and the magnitude of reflectance of an equal length transmission line with an OrBIT is shown by graph 803. Both graphs show that the actual reflectance of tested transmission lines is below −15 dB. Thus, the present invention is capable of functioning with substantially minimal degradation compared to a straight transmission line.

FIG. 8B is a graph showing a comparison of the magnitude of loss between a straight transmission line and a transmission line with an OrBIT. The axes are the same as described with respect to FIG. 8A. Graph 805 shows the magnitude of loss for a straight transmission line, while graph 807 shows the magnitude of loss for a transmission line with an OrBIT. As shown by FIG. 8B, the magnitude of loss is substantially similar for both transmission lines. Thus, a transmission line according to the present invention produces substantially no degradation in performance.

Although the present invention has been described with reference to particular embodiments, it will be understood to those skilled in the art that the invention is capable of a variety of alternative embodiments within the spirit of the appended claims.

1. An apparatus for testing one or more portions of an electrical device, comprising:
a discontinuous transmission line; and
at least one waveguide selectively positioned near each end of the discontinuity;
wherein the one or more portions are tested without being removed from the electrical device.

2. The apparatus according to claim 1, wherein the waveguide comprises a coplanar waveguide.

3. The apparatus according to claim 1, wherein the discontinuous transmission line is selectively positioned between the one or more portions of the electrical device.

4. The apparatus according to claim 1, wherein the discontinuous transmission line is operatively connected based on a ribbon bond.

5. The apparatus according to claim 4, wherein the one or more portions are capable of communicating when the discontinuous transmission line is operatively connected.

6. The apparatus according to claim 3, wherein the electrical device is manufactured onto a substrate.

7. The apparatus according to claim 6, wherein the discontinuous transmission line and the at least one waveguide is manufactured onto the substrate at substantially the same time as the electrical device.

8. The apparatus according to claim 7, wherein the total additional cost of manufacturing the discontinuous transmission line and the at least one waveguide onto the substrate is less than about 1%.

9. The apparatus according to claim 7, wherein the total additional cost of manufacturing the discontinuous transmission line and the at least one waveguide onto the substrate is less than about 0.5%.

10. An apparatus for testing an electrical device, comprising:
a discontinuous transmission line; and
at least two coplanar waveguides selectively positioned near each end of the discontinuity;
wherein the discontinuous transmission line is selectively positioned between two or more portions of the electrical device.

11. The apparatus according to claim 10, wherein the electrical device comprises a microstripline circuit.

12. The apparatus according to claim 10, wherein the electrical device is manufactured onto a substrate.

13. The apparatus according to claim 12, wherein the discontinuous transmission line and the at least two coplanar waveguides are manufactured onto the substrate at substantially the same time as the electrical device.

14. The apparatus according to claim 12, wherein the total additional cost of manufacturing the discontinuous transmission line and the at least two coplanar waveguides onto the substrate is less than about 0.5%.

15. The apparatus according to claim 10, wherein the discontinuous transmission line is operatively connected based on a ribbon bond.

16. The apparatus according to claim 15, wherein the two or more portions of the electrical device are capable of communicating when the transmission line is operatively connected.

17. A method for testing an electrical device, wherein the electrical device comprises two or more portions, comprising:
electrically isolating the two or more portions based on a discontinuous transmission line; and
selectively positioning at least two waveguides near each end of the discontinuous transmission line;
wherein the two or more portions may be tested without being removed from the electrical device.

18. The method according to claim 17, wherein the two or more portions are operatively connectable by connecting the discontinuous transmission line using a ribbon bond.

19. The method according to claim 17, further comprising testing each of the two or more portions by probing the discontinuous transmission line and the at least two waveguides.

20. The method according to claim 19, the probing comprises selectively positioning a GSG probe.

21. The method according to claim 17, wherein the electrically isolating comprises manufacturing the two or more portions and the discontinuous transmission line on a substrate at substantially the same time.

22. The method according to claim 21, wherein the selectively positioning comprises manufacturing the at least two waveguides onto the substrate at substantially the same time as the two or more portions and the discontinuous transmission line.
